(19) United States
(12) Patent Application Publication
(10) Pub. No.: US 2005/0184404 A1
(43) Pub. Date: Aug. 25, 2005

(54) Photosensitive semiconductor package with support member and method for fabricating the same

(75) Inventors: Chih-Ming Huang, Taichung Hsien (TW); Cheng-Hsu Hsiao, Taichung Hsien (TW); Chien-Ping Huang, Taichung Hsien (TW)

Correspondence Address: Mr. Peter F. Corless, EDWARDS & ANGELL, LLP, 101 Federal Street, Boston, MA, 02110, US

(73) Assignee: Siliconware Precision Industries Co., Ltd.

(21) Appl. No.: 10/835,343

(22) Filed: Apr. 28, 2004

(30) Foreign Application Priority Data
Feb. 23, 2004 (TW) 093104417

(51) Int. Cl. H01L 21/48; H01L 23/28

(52) U.S. Cl. 257/787; 438/124; 438/127

(57) ABSTRACT

A photosensitive semiconductor package with a support member and its fabrication method are provided. The support member having a receiving space is placed on an upper surface of a substrate. An encapsulation body is formed on the substrate and bonded with an outer wall of the support member. At least one chip is mounted on a predetermined area of the substrate exposed via the receiving space, and is electrically connected to the substrate. A light-permeable lid is attached to the support member and the encapsulation body to seal the receiving space. A plurality of solder balls or contact lands are formed on a lower surface of the substrate. By provision of the support member, there is no need to use an insert mold, such that the substrate would not be damaged by the insert mold, and bond fingers on the substrate would not be contaminated by the insert mold.

### FIELD OF THE INVENTION

The present invention relates to semiconductor packages and fabrication methods thereof, and more particularly, to a photosensitive semiconductor package in which a support member having a receiving space is mounted on a substrate for receiving at least one photosensitive chip in the receiving space, and a method for fabricating the semiconductor package.

### BACKGROUND OF THE INVENTION

Semiconductor packages are electronic devices for accommodating active components such as semiconductor chips, whose structure is primarily composed of a chip mounted on a substrate and electrically connected to the substrate via conductive elements such as bonding wires, and an encapsulation body formed by a resin compound (such as epoxy resin, etc.) on the substrate to encapsulate and protect the chip and bonding wires against external moisture and contaminant. The resin compound forming the encapsulation body is usually opaque or non-transparent, thereby making a photosensitive chip such as CMOS (complementary metal oxide semiconductor) chip that requires light for operation not suitably incorporated in such a semiconductor package.

Accordingly, U.S. Pat. Nos. 6,262,479 and 6,590,269 disclose a semiconductor package suitable for a photosensitive chip, whose fabrication steps are shown in FIGS. 5A and 5B. Referring to FIG. 5A, a molding process is carried out to form an encapsulation dam 13 on the substrate 11. During molding, an encapsulation mold is used comprising an upper mold 15 having a cavity 150 and a protruded insert portion 151 formed in the cavity 150, and a lower mold 16; thus this encapsulation mold is customarily named “insert mold” hereinafter. The substrate 11 is clamped between the upper and lower molds 15, 16, with the insert portion 151 coming into contact with the substrate 11 to cover the predetermined area for chip-attachment and wire-bonding on the substrate 11. A resin compound (such as epoxy resin) is injected to the cavity 150 to form the encapsulation dam 13 on the substrate 11. By provision of the insert portion 151, the predetermined area for chip-attachment and wire-bonding on the substrate 11 would not be encapsulated by the encapsulation dam 13 and is exposed after the upper and lower molds 15, 16 are removed from the substrate 11, as shown in FIG. 5B. Then, at least one photosensitive chip 10 is mounted on the exposed area of the substrate 11, and a plurality of bonding wires 12 are formed and bonded to bond fingers 110 on the substrate 10 so as to electrically connect the chip 10 to the substrate 11. And finally with a light-permeable lid 14 attached to the encapsulation dam 13, the semiconductor package is fabricated.

However, the above semiconductor package may suffer significant drawbacks. The insert portion of the upper mold covers the predetermined area on the substrate not to be encapsulated by the resin compound during molding. However, it is not easy to properly control the clamping force between the insert portion and the substrate. If the insert portion is not sufficiently clamped on the substrate, flash of the resin compound may occur between the insert portion and the substrate and thus contaminates the predetermined area on the substrate for chip-attachment and wire-bonding. If the insert portion is too strongly pressed on the substrate, the substrate may be structurally damaged by the insert portion. Moreover, the direct contact between the insert portion and the substrate may easily contaminate the bond fingers on the substrate where the bonding wires are bonded. The contaminated bond fingers make the bonding wires not able to be perfectly and firmly bonded to the bond fingers, thereby degrading the quality of electrical connection for the semiconductor package. Further, the insert mold is cost-ineffective to fabricate, which requires formation of the insert portion according to the size of substrate or predetermined area on the substrate to be covered by the insert portion. In other words, if the size of substrate or area on the substrate to be covered changes, a new mold with correspondingly-sized insert portion is required, which would undesirably increase the fabrication cost and complicate the fabrication processes for the semiconductor package.

Therefore, the problem to be solved herein is to provide a semiconductor package with a photosensitive chip, which can overcome the above drawbacks to prevent the substrate from damage, avoid contamination to bond fingers on the substrate, and reduce the fabrication cost.

### SUMMARY OF THE INVENTION

An objective of the present invention is to provide a photosensitive semiconductor package with a support member and a method for fabricating the same, without the use of an insert mold for forming an encapsulation body on a substrate, such that the fabrication cost can be reduced and the fabrication processes can be simplified.

Another objective of the present invention is to provide a photosensitive semiconductor package with a support member and a method for fabricating the same, without the use of an insert mold for forming an encapsulation body on a substrate, so as to prevent the substrate from being damaged by the insert mold and avoid contamination from the insert mold to bond fingers on the substrate.

In accordance with the above and other objectives, the present invention proposes a photosensitive semiconductor package, comprising a substrate having an upper surface and a lower surface; a support member having a receiving space, the support member placed on the upper surface of the substrate, with a predetermined area on the upper surface of the substrate exposed via the receiving space; an encapsulation body formed on the upper surface of the substrate and bonded with an outer wall of the support member; at least one chip mounted on the exposed area of the upper surface of the substrate and electrically connected to the substrate; a lid attached to the support member and the encapsulation body to seal the receiving space; and a plurality of input/output (I/O) connections formed on the lower surface of the substrate.

The above photosensitive semiconductor package can be fabricated by the steps comprising: preparing a substrate having an upper surface and a lower surface; placing a support member having a receiving space on the upper surface of the substrate, with a predetermined area on the upper surface of the substrate exposed via the receiving space; performing a molding process using an upper mold and a lower mold, the upper mold having a cavity, and placing the substrate between the upper mold and the lower mold, wherein the support member is received in the cavity and in contact with an inner wall of the cavity; and injecting a molding compound to the cavity to fill a space between the inner wall of the cavity and an outer wall of the support member so as to form an encapsulation body on the upper surface of the substrate, the encapsulation body bonded with the outer wall of the support member; removing the upper mold and the lower mold from the substrate such that the predetermined area on the upper surface of the substrate is exposed; mounting at least one chip on the exposed area of the upper surface of the substrate, and electrically connecting the chip to the substrate; attaching a lid to the support member and the encapsulation body to seal the receiving space; and forming a plurality of I/O connections on the lower surface of the substrate.

The above photosensitive semiconductor package can also be fabricated in a batch manner by the steps comprising: preparing a substrate strip comprising a plurality of substrates, each of the substrates having an upper surface and a lower surface; preparing a support member plate comprising a plurality of support members, each of the support members having a receiving space, with at least one tie bar connecting the adjacent support members together, and placing the support member plate on the substrate strip, wherein each of the support members is located on the upper surface of a corresponding one of the substrates, and a predetermined area on the upper surface of each of the substrates is exposed via the receiving space of the corresponding support member; performing a molding process using an upper mold and a lower mold, the upper mold having a cavity, and placing the substrate strip between the upper mold and the lower mold, wherein the support members are received in the cavity and in contact with an inner wall of the cavity; and injecting a molding compound to the cavity to fill a space between the inner wall of the cavity and an outer wall of each of the support members so as to form an encapsulation body on the substrate strip, the encapsulation body bonded with the outer walls of the support members; removing the upper mold and the lower mold from the substrate strip such that the predetermined area on the upper surface of each of the substrates is exposed; mounting at least one chip on the exposed area of the upper surface of each of the substrates, and electrically connecting the chip to the corresponding substrate; attaching at least one lid to the support members and the encapsulation body to seal the receiving spaces; performing a singulation process to cut the encapsulation body into package units; and forming a plurality of I/O connections on the lower surface of each of the substrates.

Moreover, the outer wall of the support member can be formed with at least one lock portion so as to enhance the bonding between the support member and the encapsulation body.

In the above semiconductor package, the chip (such as photosensitive chip) and bonding wires for electrically connecting the chip to the substrate are received in the receiving space of the support member and hermetically isolated from the atmosphere by means of the lid that is light permeable. Light can go through the lid and reach the photosensitive chip that requires light for operation. The I/O connections such as solder balls or contact lands formed on the lower surface of the substrate allow the chip to be electrically connected to an external device such as printed circuit board.

By the above photosensitive semiconductor package and its fabrication method, a support member having a receiving space is mounted on the substrate, and the size of the support member and receiving space can be made or adjusted according to the size of the substrate or the size of the predetermined die-bonding and wire-bonding area on the substrate to be exposed via the receiving space. Therefore, the molding process for forming the encapsulation body only requires the common encapsulation mold comprising the upper mold (having a cavity) and the lower mold, making all types of substrates suitably undergo the molding process in the use of this encapsulation mold to fabricate variably sized packages, such that an insert mold with a protruded insert portion is not needed. Moreover, the support member is cost-effective to fabricate, thereby not significantly increasing the overall package fabrication cost. Without the need to use the insert mold, the fabrication cost can be effectively reduce as not having to prepare the insert mold with the insert portion that must be made according to the size of substrate or predetermined area on the substrate to be covered by the insert portion. The single universal encapsulation mold suitably applied to fabrication of different packages also simplifies the fabrication processes. Further since the insert mold is not required, the substrate would not be damaged by unduly pressure from the insert portion of the insert mold that is in contact with the substrate, and the bond fingers on the substrate can be prevented against contamination from the insert portion in contact with the substrate. As a result, the bonding wires that electrically connect the chip to the substrate can be perfectly and strongly bonded to the uncontaminated bond fingers, thereby assuring the quality of electrical connection for the semiconductor package.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a semiconductor package according to the invention;

FIGS. 2A-2F are schematic diagrams showing a series of procedural steps of a method for fabricating the semiconductor package of FIG. 1;

FIG. 3 is a cross-sectional view of a semiconductor package having a support member according to another example of the invention;

FIGS. 4A-4I are schematic diagrams showing another series of procedural steps of a method for fabricating the semiconductor package of FIG. 1; and

FIGS. 5A and 5B (PRIOR ART) are schematic diagrams showing a series of procedural steps for fabricating a conventional semiconductor package.

### DETAILED DESCRIPTION OF THE PREFERRED EMBODIMENTS

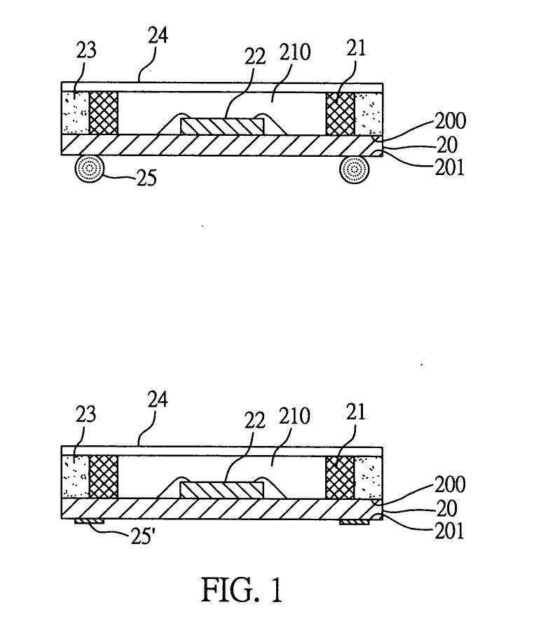

The preferred embodiments of a photosensitive semiconductor package and its fabrication method proposed in the present invention are described with reference to FIGS. 1, 2A-2F, 3 and 4A-4I.

As shown in FIG. 1, the semiconductor package comprises a substrate 20 having an upper surface 200 and a lower surface 201; a support member 21 having a receiving space 210, the support member 21 placed on the upper surface 200 of the substrate 20, with a predetermined area on the upper surface 200 of the substrate 20 exposed via the receiving space 210; an encapsulation body 23 formed on the upper surface 200 of the substrate 20 and bonded with an outer wall of the support member 21; at least one chip 22 mounted on the exposed area of the upper surface 200 of the substrate 20 and electrically connected to the substrate 20; a light-permeable lid 24 attached to the support member 21 and the encapsulation body 23 to seal the receiving space 210; and a plurality of input/output (I/O) connections (such as solder balls 25 or contact lands 25′) formed on the lower surface 201 of the substrate 20.

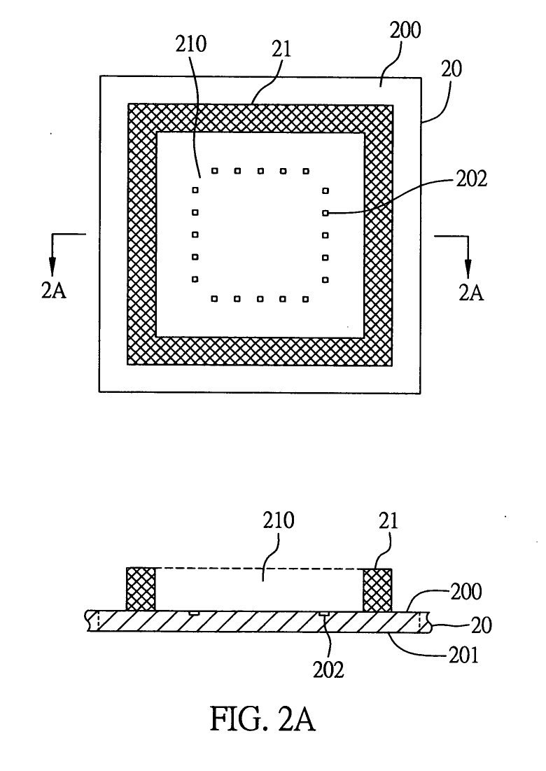

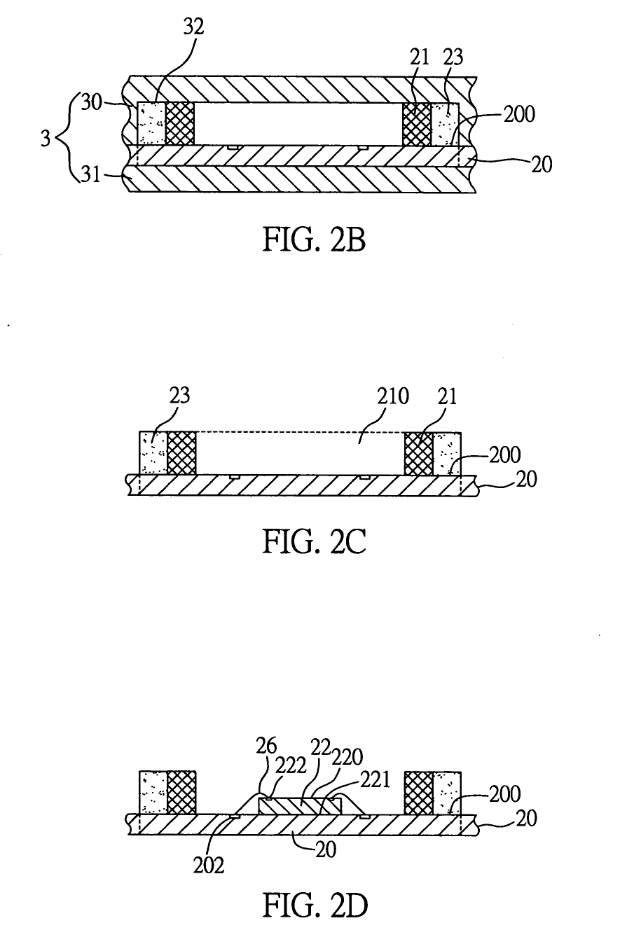

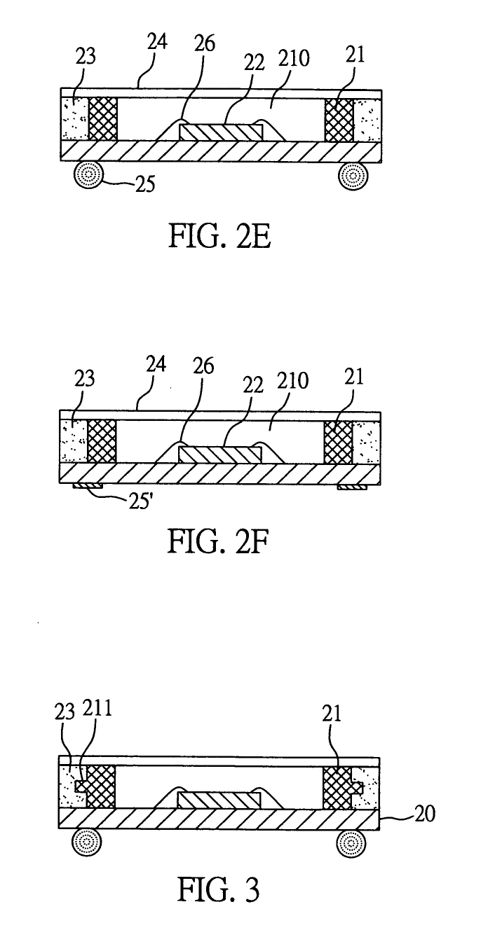

The above semiconductor package can be fabricated by the steps shown in FIGS. 2A to 2F.

Referring to FIG. 2A (top view and cross-sectional view along line 2A-2A), the first step is to prepare a substrate 20 having an upper surface 200 and a lower surface 201, with a plurality of bond fingers 202 formed on the upper surface 200. The substrate 20 can be made of epoxy resin, polyimide resin, BT (bismaleimide triazine) resin or FR4 resin. And a support member 21 having a receiving space 210 is prepared. The support member 21 is preferably shaped as a frame to form the receiving space 210. The support member 21 can be made of a metallic material such as copper or aluminum, or a non-metallic material such as the above substrate material or thermal resistant plastic material. Then, the support member 21 is placed on the upper surface 200 of the substrate 20, to allow a predetermined die-bonding and wire-bonding area (including the bond fingers 202) on the upper surface 200 of the substrate 20 to be exposed via the receiving space 210. The support member 21 can be attached to the substrate 20 by an adhesive (not shown), or directly placed on the substrate 20.

Referring to FIG. 2B, a molding process is performed using an encapsulation mold 3 having an upper mold 30 and a lower mold 31, wherein the upper mold 30 is formed with a cavity 32. The substrate 20 is placed in the encapsulation mold 3 and clamped between the upper mold 30 and the lower mold 31, wherein the support member 21 on the substrate 20 is received in the cavity 32 and in contact with an inner wall of the cavity 32. A molding compound (such as epoxy resin) is injected to the cavity 32 to fill a space between the inner wall of the cavity 32 and an outer wall of the support member 21. When the molding compound is cured, an encapsulation body 23 is formed on the upper surface 200 of the substrate 20 and bonded with the outer wall of the support member 21.

Referring to FIG. 2C, when the encapsulation body 23 is fabricated, the upper mold 30 and the lower mold 31 of FIG. 2B are removed from the substrate 20, such that the predetermined die-bonding and wire-bonding area on the upper surface 200 of the substrate 20, which is located in the receiving space 210 of the support member 21, is exposed.

Referring to FIG. 2D, a die-bonding process is performed to mount at least one photosensitive chip 22 such as CMOS (complementary metal oxide semiconductor) chip on the exposed area of the upper surface 200 of the substrate 20 and in the receiving space 210 of the support member 21. The chip 22 has an active surface 220 formed with a plurality of bond pads 222 thereon, and an inactive surface 221 opposed to the active surface 220, allowing the inactive surface 221 of the chip 22 to be attached to the substrate 20. Then, a wire-bonding process is performed to form a plurality of bonding wires 26 such as gold wires that are bonded to the bond pads 222 on the chip 22 and to the bond fingers 202 on the substrate 20, making the chip 22 electrically connected to the substrate 20 via the bonding wires 26. The die-bonding and wire-bonding processes are known in the art and not to be further detailed here.

Finally, referring to FIG. 2E, a lid 24 made of a light-permeable material is attached to the support member 21 and the encapsulation body 23 to seal the receiving space 210, such that the chip 22 and the bonding wires 26 received in the receiving space 210 are isolated from the atmosphere by means of the lid 24. Then, a plurality of input/output (I/O) connections 25, 25′ are formed on the lower surface 201 of the substrate 20, wherein the I/O connections can be solder balls 25, or contact lands 25′ in FIG. 2F. If the I/O connections are solder balls 25 (FIG. 2E), the fabricated semiconductor package is a BGA (ball grid array) package; if the I/O connections are contact lands 25′ (FIG. 2F), the fabricated semiconductor package is a LGA (land grid array) package.

As shown in FIG. 3, the outer wall of the support member 21 can be formed with at least one lock portion 211 to be firmly bonded with the encapsulation body 23, so as to enhance the bonding between the support member 21 and the encapsulation body 23.

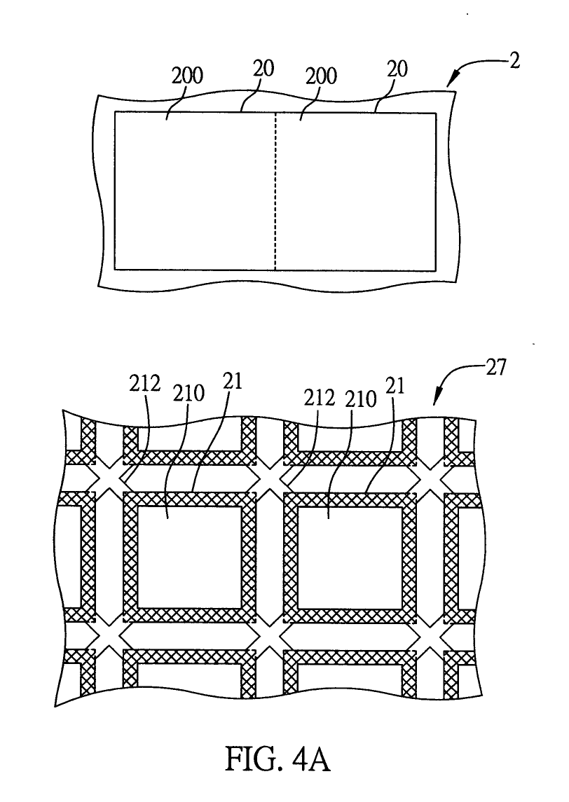

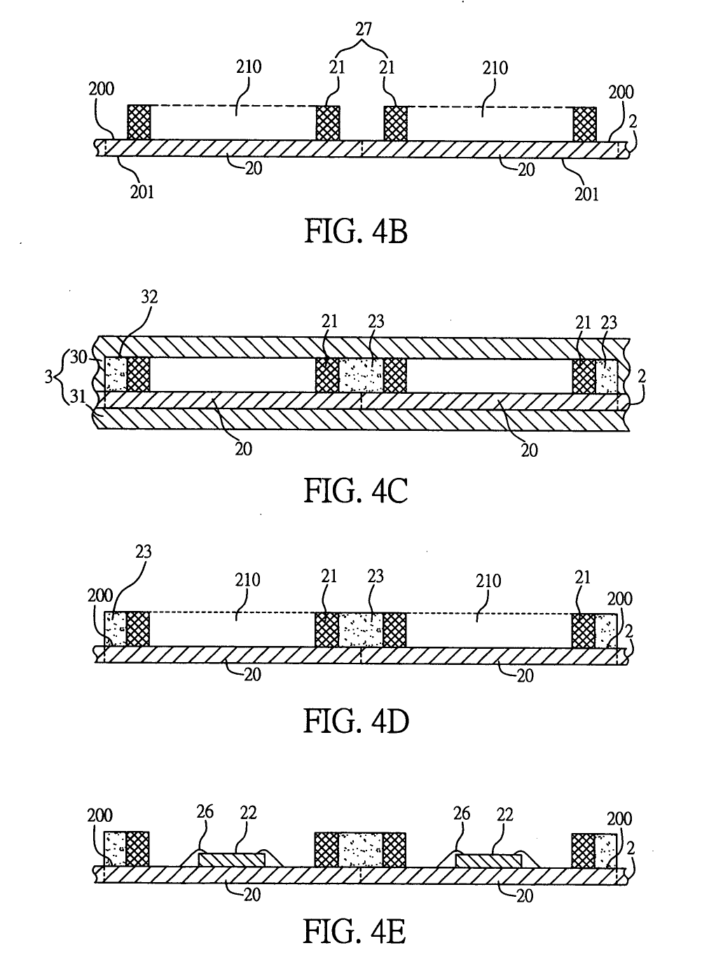

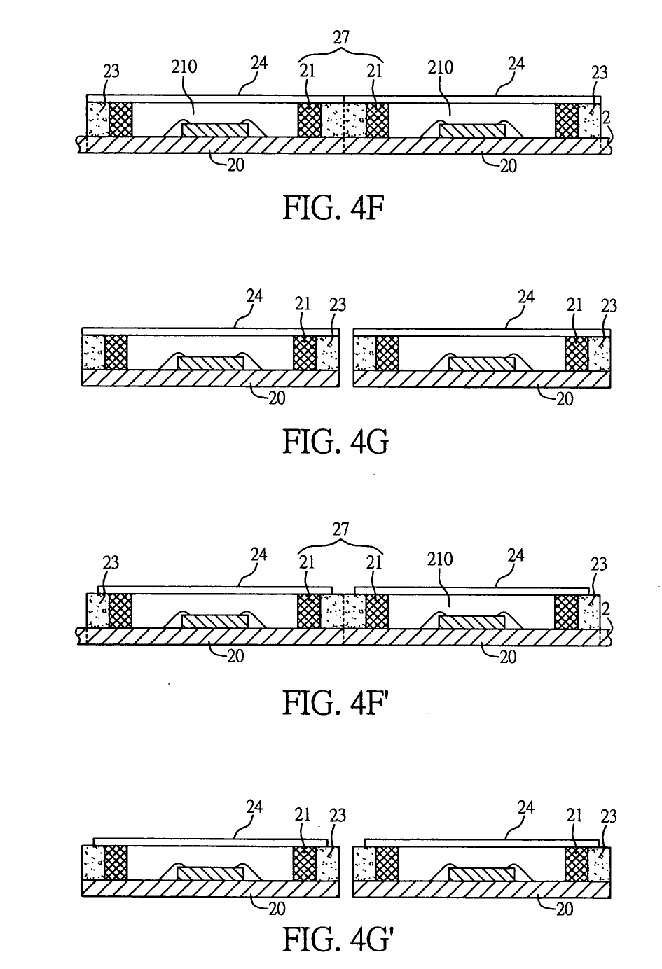

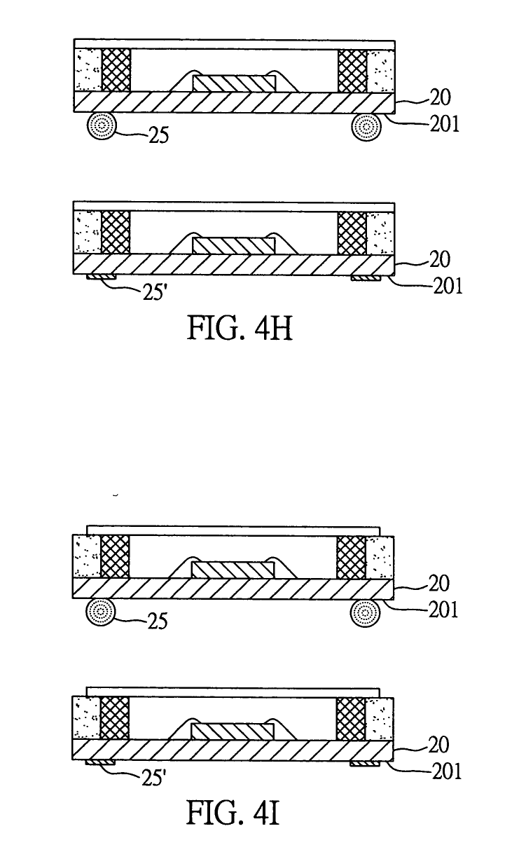

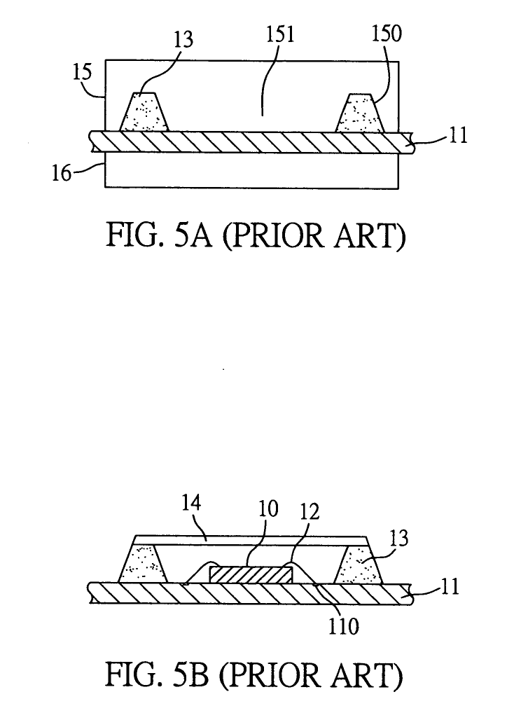

In another embodiment, the semiconductor package according to the present invention can be fabricated in a batch manner by the steps shown in FIGS. 4A to 4I.

Referring to FIG. 4A (top view), the first step is to prepare a substrate strip 2 comprising a plurality of integrally formed substrates 20, each of the substrates 20 having an upper surface 200 and a lower surface 201 (FIG. 4B); the substrate 20 is structurally the same as the above substrate 20 in FIG. 2A. A support member plate 27 is prepared comprising a plurality of support members 21, each of the support members 21 having a receiving space 210; the support member 21 is structurally the same as the above support member 21 in FIG. 2A. The adjacent support members 21 are connected together via one or more tie bars 212, and the tie bars 212 are made smaller in thickness than the support member 21 in the use of half-etching technique.

Referring to FIG. 4B, the support member plate 27 is attached via an adhesive (not shown) or directly placed on the substrate strip 2, wherein each of the support members 21 is located on the upper surface 200 of a corresponding one of the substrates 20, and a predetermined die-bonding and wire-bonding area on the upper surface 200 of each of the substrates 20 is exposed via the receiving space 210 of the corresponding support member 21. The tie bars 212 connecting the adjacent support members 21 together can hold the support members 21 in position on the corresponding substrates 20.

Referring to FIG. 4C, a molding process is performed using an encapsulation mold 3 having an upper mold 30 and a lower mold 31, wherein the upper mold 30 is formed with a cavity 32. The above substrate strip 2 is placed and clamped between the upper mold 30 and the lower mold 31, wherein the support members 21 on the substrates 20 are received in the cavity 32 and in contact with an inner wall of the cavity 32. A molding compound (such as epoxy resin) is injected to the cavity 32 to fill a space between the inner wall of the cavity 32 and an outer wall of each of the support members 21, wherein the tie bars 212 having smaller thickness can be encapsulated by the molding compound. When the molding compound is cured, an encapsulation body 23 is formed on the substrate strip 2 and bonded with the outer walls of the support members 21.

Referring to FIG. 4D, when the encapsulation body 23 is fabricated, the upper mold 30 and the lower mold 31 of FIG. 4C are removed from the substrate strip 2, such that the predetermined die-bonding and wire-bonding area on the upper surface 200 of each of the substrates 20, which is located in the receiving space 210 of the corresponding support member 21, is exposed.

Referring to FIG. 4E, conventional die-bonding and wire-bonding processes are performed. At least one photosensitive chip 22 is mounted on the exposed are of the upper surface 200 of each of the substrates 20 and electrically connected to the corresponding substrate 20 via a plurality of bonding wires 26.

Referring to FIG. 4F, a light-permeable lid 24 is attached to the support member plate 27 and the encapsulation body 23 to seal all the receiving spaces 210 of the support members 21. Then, as shown in FIG. 4G, a singulation process is performed to cut the lid 24, the encapsulation body 23, the support member plate 27 and the substrate strip 2 along the cutting lines (dotted lines in FIG. 4F) to separate apart the plurality of support members 21 and the plurality of substrates 20.

Alternatively, as shown in FIG. 4F′, a plurality of light-permeable lids 24 are attached to the support member plate 27 and the encapsulation body 23, wherein each of the lids 24 is located on a corresponding one of the support members 21 and covers the receiving space 210 of the corresponding support member 21. Then, as shown in FIG. 4G′, the singulation process is performed to cut the encapsulation body 23, the support member plate 27 and the substrate strip 2 along the cutting lines (dotted lines in FIG. 4F′) to separate apart the plurality of support members 21 and the plurality of substrates 20.

Finally, referring to FIG. 4H or 4I, a plurality of I/O connections such as solder balls 25 or contact lands 25′ are formed on the lower surface 201 of the substrate 20 in each of the semi-fabricated package structures of FIG. 4G or 4G′, such that a plurality of individual semiconductor packages are fabricated.

In the above fabricated semiconductor package, the chip (photosensitive chip) and the bonding wires for electrically connecting the chip to the substrate are received in the receiving space of the support member and hermetically isolated from the atmosphere by means of the light-permeable lid. Light can go through the lid and reach the photosensitive chip that requires light for operation. The I/O connections such as solder balls or contact lands formed on the lower surface of the substrate allow the chip to be electrically connected to an external device such as printed circuit board (not shown).

By the above photosensitive semiconductor package and its fabrication method, a support member having a receiving space is mounted on the substrate, and the size of the support member and receiving space can be made or adjusted according to the size of the substrate or the size of the predetermined die-bonding and wire-bonding area on the substrate to be exposed via the receiving space. Therefore, the molding process for forming the encapsulation body only requires the common encapsulation mold comprising the upper mold (having a cavity) and the lower mold, making all types of substrates suitably undergo the molding process in the use of this encapsulation mold to fabricate variably sized packages, such that an insert mold with a protruded insert portion is not needed. Moreover, the support member is cost-effective to fabricate, thereby not significantly increasing the overall package fabrication cost. Without the need to use the insert mold, the fabrication cost can be effectively reduce as not having to prepare the insert mold with the insert portion that must be made according to the size of substrate or predetermined area on the substrate to be covered by the insert portion. The single universal encapsulation mold suitably applied to fabrication of different packages also simplifies the fabrication processes. Further since the insert mold is not required, the substrate would not be damaged by unduly pressure from the insert portion of the insert mold that is in contact with the substrate, and the bond fingers on the substrate can be prevented against contamination from the insert portion in contact with the substrate. As a result, the bonding wires that electrically connect the chip to the substrate can be perfectly and strongly bonded to the uncontaminated bond fingers, thereby assuring the quality of electrical connection for the semiconductor package.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A photosensitive semiconductor package, comprising:
a substrate having an upper surface and a lower surface;
a support member having a receiving space, the support member placed on the upper surface of the substrate, with a predetermined area on the upper surface of the substrate exposed via the receiving space;
an encapsulation body formed on the upper surface of the substrate and bonded with an outer wall of the support member;
at least one chip mounted on the exposed area of the upper surface of the substrate and electrically connected to the substrate; and
a lid attached to the support member and the encapsulation body to seal the receiving space.

2. The semiconductor package of claim 1, further comprising a plurality of solder balls or contact lands formed on the lower surface of the substrate.

3. The semiconductor package of claim 1, wherein the support member is made of a metallic material or a non-metallic material.

4. The semiconductor package of claim 3, wherein the non-metallic material is a substrate material or a thermal resistant plastic material.

5. The semiconductor package of claim 4, wherein the substrate material is selected from the group consisting of epoxy resin, polyimide resin, BT (bismaleimide triazine) resin, and FR4 resin.

6. The semiconductor package of claim 1, wherein the outer wall of the support member is formed with at least one lock portion to be firmly bonded with the encapsulation body.

7. A method for fabricating a photosensitive semiconductor package, comprising the steps of:
preparing a substrate having an upper surface and a lower surface;
placing a support member having a receiving space on the upper surface of the substrate, with a predetermined area on the upper surface of the substrate exposed via the receiving space;
performing a molding process using an upper mold and a lower mold, the upper mold having a cavity, and placing the substrate between the upper mold and the lower mold, wherein the support member is received in the cavity and in contact with an inner wall of the cavity; and injecting a molding compound to the cavity to fill a space between the inner wall of the cavity and an outer wall of the support member so as to form an encapsulation body on the upper surface of the substrate, the encapsulation body bonded with the outer wall of the support member;
removing the upper mold and the lower mold from the substrate such that the predetermined area on the upper surface of the substrate is exposed;
mounting at least one chip on the exposed area of the upper surface of the substrate, and electrically connecting the chip to the substrate; and
attaching a lid to the support member and the encapsulation body to seal the receiving space.

8. The method of claim 7, further comprising: forming a plurality of solder balls or contact lands on the lower surface of the substrate.

9. The method of claim 7, wherein the support member is made of a metallic material or a non-metallic material.

10. The method of claim 9, wherein the non-metallic material is a substrate material or a thermal resistant plastic material.

11. The method of claim 10, wherein the substrate material is selected from the group consisting of epoxy resin, polyimide resin, BT (bismaleimide triazine) resin, and FR4 resin.

12. The method of claim 7, wherein the outer wall of the support member is formed with at least one lock portion to be firmly bonded with the encapsulation body.

13. A method for fabricating a photosensitive semiconductor package, comprising the steps of:
preparing a substrate strip comprising a plurality of substrates, each of the substrates having an upper surface and a lower surface;
preparing a support member plate comprising a plurality of support members, each of the support members having a receiving space, with at least one tie bar connecting the adjacent support members together, and placing the support member plate on the substrate strip, wherein each of the support members is located on the upper surface of a corresponding one of the substrates, and a predetermined area on the upper surface of each of the substrates is exposed via the receiving space of the corresponding support member;
performing a molding process using an upper mold and a lower mold, the upper mold having a cavity, and placing the substrate strip between the upper mold and the lower mold, wherein the support members are received in the cavity and in contact with an inner wall of the cavity; and injecting a molding compound to the cavity to fill a space between the inner wall of the cavity and an outer wall of each of the support members so as to form an encapsulation body on the substrate strip, the encapsulation body bonded with the outer walls of the support members;
removing the upper mold and the lower mold from the substrate strip such that the predetermined area on the upper surface of each of the substrates is exposed;
mounting at least one chip on the exposed area of the upper surface of each of the substrates, and electrically connecting the chip to the corresponding substrate;
attaching at least one lid to the support members and the encapsulation body to seal the receiving spaces; and
performing a singulation process to cut the encapsulation body, the support member plate and the substrate strip to separate apart the plurality of substrates and the plurality of support members.

14. The method of claim 13, wherein the lid covers all the receiving spaces of the support members and is cut in the singulation process.

15. The method of claim 13, wherein a plurality of the lids are each attached to a corresponding one of the support members and each covers the corresponding receiving space.

16. The method of claim 13, further comprising: forming a plurality of solder balls or contact lands on the lower surface of each of the substrates.

17. The method of claim 13, wherein the support member is made of a metallic material or a non-metallic material.

18. The method of claim 17, wherein the non-metallic material is a substrate material or a thermal resistant plastic material.

19. The method of claim 18, wherein the substrate material is selected from the group consisting of epoxy resin, polyimide resin, BT (bismaleimide triazine) resin, and FR4 resin.

20. The method of claim 13, wherein the outer wall of the support member is formed with at least one lock portion to be firmly bonded with the encapsulation body.

21. The method of claim 13, wherein the tie bar is smaller in thickness than the support member.

22. The method of claim 21, wherein the tie bar is encapsulated by the encapsulation body.
